(19) United States
(12) Patent Application Publication
(10) Pub. No.: US 2013/0335924 A1
(43) Pub. Date: Dec. 19, 2013

(54) OPTION BOARD EXCHANGE MECHANISM IN DISPLAY APPARATUS, AND DISPLAY APPARATUS

(71) Applicants: Yoshihiro Takechi, Tokyo (JP); Toshiyuki Noguchi, Tokyo (JP)

(72) Inventors: Yoshihiro Takechi, Tokyo (JP); Toshiyuki Noguchi, Tokyo (JP)

(21) Appl. No.: 14/001,163

(22) PCT Filed: Feb. 23, 2011
(86) PCT No.: PCT/JP2011/054033

§ 371 Date: Aug. 22, 2013

(51) Int. Cl. H05K 5/00

(52) U.S. Cl. CPC H05K 5/0017
USPC 361/725

(57) ABSTRACT

Different board-type devices can be selectably attached to a device attachment slot of a display apparatus. A first board-type device has a depth corresponding to the device main body thereof. A first female connector of the first board-type device inserted to the device attachment slot is connected to a first male connector of the apparatus. In a second board-type device having a shape different from the first board-type device, the device main body thereof is connected to a connector via two adaptor boards having a step therebetween. Accordingly, in the second board-type device, even the device main body, which has a smaller depth than the chassis whose depth coincides with that of the first board-type device, and can be selectably attached to the device attachment slot with respect to the first board-type.

### TECHNICAL FIELD

The present invention relates to an option board exchange mechanism in a display apparatus, and also to a display apparatus.

### BACKGROUND ART

A display apparatus such as a monitor can receive over-the air or cable TV (television) programs or the like by attaching to the display apparatus, a tuner board having a TV tuner function, an authentication card for unscrambling scrambled programs (typically for cable TV), or the like.

In order that a plurality of display apparatuses arranged in both horizontal and vertical directions can function as a large-sized monitor, a chain board may be attached to each display apparatus. Additionally, when attaching an SBC (small board computer) that functions as a personal computer, the relevant display apparatus can function as a monitor and an all-in-one personal computer.

As shown in Patent-Document 1, a known display apparatus has a slot to which a board-type device can be detachably attached, so that one of board-type devices (option boards) having various functions as described above can be exchangeably attached to one monitor.

### PRIOR ART DOCUMENT

### Patent Document

Patent Document 1: Japanese Unexamined Patent Application, First Publication No. 2007-250926.

### DISCLOSURE OF INVENTION

### Problem to be Solved by the Invention

Generally, board-type devices are standardized so that external dimensions and connectors for electric connection have unified standards for board-type devices that differ from each other. However, accompanied with downsizing and sophistication of devices, multiple standards that answer the needs of the age are present, where different standards define different external dimensions for board-type devices and different connectors for electric connection.

In such a case, in order to selectively attach one of board-type devices based on different standards to a display apparatus, slots corresponding to the respective standards must be provided in the display apparatus. Therefore, a space for the slots is required, which constricts the downsizing of the display apparatus.

In consideration of the above problem, an object of the present invention is to provide an option board exchange mechanism in a display apparatus, and a corresponding display apparatus, by which board-type devices based on different standards can be exchangeably attached to the display apparatus, and downsizing of the display apparatus can be realized.

### Means for Solving the Problem

In order to achieve the above object, the present invention provides the followings.

That is, the present invention provides an option board exchange mechanism in a display apparatus to which board-type devices of different types can be selectably attached, wherein the display apparatus comprises:

a device housing slot that extends from a slot opening formed in a chassis of the apparatus towards the inside of the chassis and can selectably contain at least a first board-type device and a second board-type device which have different forms; and

an apparatus-side connector provided at an innermost part of the device housing slot;

the first board-type device comprises a first device main body, a first chassis that supports the first device main body, and a first device-side connector that is connected to the apparatus-side connector; and

the second board-type device comprises:

a second device main body that has a smaller depth dimension than that of the first device main body with respect to an insertion direction for the device housing slot;

a second chassis that supports the first device main body and has the same depth dimension as that of the first chassis,;

a second device-side connector that is connected to the apparatus-side connector; and

a connection wiring unit fastened to the second chassis, where the connection wiring unit electrically connects the second device main body to the second device-side connector.

To the device housing slot of the display apparatus, the first board-type device and the second board-type device which have different forms can be selectably attached.

When attaching the first board-type device, it is inserted from the slot opening into the device housing slot, and the first device-side connector is connected to the apparatus-side connector.

When attaching the second board-type device, it is inserted from the slot opening into the device housing slot, and the second device-side connector is connected to the apparatus-side connector. In this process, the second device main body of the second board-type device has a smaller depth dimension than that of the first device main body. In contrast, the first chassis and the second chassis have the same depth dimension so as to establish compatibility therebetween. Therefore, the second device main body and the second device-side connector are electrically connected by means of the connection wiring unit fastened to the second chassis.

Although the first chassis and the second chassis may have the same width, this is not a limiting condition.

In the second chassis, it is possible that a back side in the insertion direction for the device housing slot has a first width that is the same as a width of the first chassis, and a front side in said insertion direction has a second width that is greater than the width of the first chassis. Accordingly, in the second chassis, the second device main body having a width greater than the width of the first chassis can be contained in the front side in the insertion direction.

In this case, in the device housing slot, a back side in said insertion direction has a width that corresponds to the first width, and a front side in said insertion direction has a width that corresponds to the second width.

It is possible to provide a cover for closing the slot opening. Although the cover may have any form. For example, the cover has a first cover body whose width corresponds to the first width, and a second cover body whose width corresponds to the second width, where the second cover body has an opening to which the first cover body can be attached.

Accordingly, when detaching the first cover body and the second cover body from the slot opening, the slot opening can have the second width so that the second chassis, that is, the second board-type device, can be inserted into the device housing slot. In addition, when detaching only the first cover body while maintaining the second cover body, the slot opening can have the first width so that the first chassis, that is, the first board-type device, can be inserted into the device housing slot.

Although the apparatus-side connector may include only one connector, it may have at least a first apparatus-side connector and a second apparatus-side connector.

In such a case, the first device-side connector is connected to at least the first apparatus-side connector, and the second device-side connector is connected to at least the second apparatus-side connector. Here, preferably, the first device-side connector and the second device-side connector are respectively connected to different apparatus-side connectors or connector combinations. For example, the first device-side connector may be connected to the first apparatus-side connector, and the second device-side connector may be connected to the second apparatus-side connector. In addition, the first device-side connector may be connected to the first apparatus-side connector, and the second device-side connector may be connected to the first apparatus-side connector and the second apparatus-side connector. Furthermore, the first device-side connector may be connected to the first apparatus-side connector and the second apparatus-side connector, and the second device-side connector may be connected to the second apparatus-side connector.

It is possible that the first apparatus-side connector is a male connector;

the second apparatus-side connector is a female connector; and

the second device-side connector has a first female connector that is connected to the first apparatus-side connector, and a second male connector that is connected to the second apparatus-side connector.

In this case, since the first apparatus-side connector is a male connector, it can be connected to the first device-side connector that is a female connector. In addition, the second apparatus-side connector is a female connector. Therefore, interconnection can be established using the second device-side connector that has the first female connector connected to the first apparatus-side connector and the second male connector connected to the second apparatus-side connector. Accordingly, the first and second device-side connectors of different types can be selectably and accurately connected to the apparatus-side connector.

The connection wiring unit may function as harness, and may be an electric circuit board.

In addition, the electric circuit board may include a first electric circuit board and a second electric circuit board. It is also possible that the first electric circuit board is connected to the second device main body; the second electric circuit board is connected to the second device-side connector; and the first electric circuit board and the second electric circuit board are arranged to have a step therebetween. Accordingly, if there is a step between the second device main body and the second device-side connector, they can be connected to each other.

The present invention also provides a display apparatus to which board-type devices of different types can be selectably attached, the display apparatus comprising:

a device housing slot that extends from a slot opening formed in a surface of a chassis of the apparatus towards the inside of the chassis and can selectably contain at least a first board-type device and a second board-type device; and

an apparatus-side connector provided at an innermost part of the device housing slot,

wherein in the device housing slot, a back side has a first width and a front side towards the slot opening has a second width that is greater than the first width.

The present invention may be a board-type device that comprises:

a device main body;

a chassis, wherein the device main body is fastened to an end of the chassis;

a device-side connector provided at the other end of the chassis; and

a connection wiring unit fastened to the chassis, where the connection wiring unit electrically connects the device main body to the device-side connector.

The device housing slot does not always contain the first board-type device and the second board-type device, but may contain three or more different board-type devices.

In each of the first board-type device and the second board-type device, the device main body installed in the relevant chassis may be of any type and be used for any purpose. The size of the device main body may also be any value if it can be contained in the relevant chassis.

### Effect of the Invention

In accordance with the present invention, the first board-type device and the second board-type device, which have different dimensions for depth, width, or the like, can be selectively attached to the device housing slot of the display apparatus. Therefore, it is unnecessary to provide a plurality of the device housing slots of different types, and thus downsizing can be realized while improving multi-functional characteristics of the display apparatus.

### BRIEF DESCRIPTION OF THE DRAWINGS

FIG. 1 is a perspective view that shows the back side of a display apparatus according to an embodiment of the present invention.

FIG. 2 is a main part perspective view that shows a view observed when the back cover of the display apparatus in FIG. 1 is detached.

FIG. 3 is a main part perspective view of a slot opening of the display apparatus, where part (a) shows a state in which only the second cover body is attached to the slot opening and the first cover body is detached, and part (b) shows a state in which the first and second cover bodies are detached from the slot opening.

FIG. 4 is a perspective view that shows a first board-type device in the embodiment of the present invention.

FIG. 5 is a perspective view that shows a state in which the first board-type device is inserted from the slot opening.

FIG. 6 is a main part perspective view that shows a state in which the device-side connector of the first board-type device is connected to the apparatus-side connector.

FIG. 7 is a perspective view that shows a state in which the first board-type device is attached to the device housing slot of the display apparatus.

FIG. 8 is a perspective view that shows a second board-type device in the embodiment.

FIG. 9 is an exploded perspective view that shows the second board-type device in FIG. 8.

FIG. 10 is a perspective view that shows a state in which the second board-type device is inserted from the slot opening.

FIG. 11 is a perspective view that shows a state in which the device-side connector of the second board-type device is connected to the apparatus-side connector of the display apparatus.

FIG. 12 is a perspective view that shows a state in which the second board-type device is attached to the device housing slot of the display apparatus.

### MODE FOR CARRYING OUT THE INVENTION

Below, a best mode for implementing the option board exchange mechanism in a display apparatus and the display apparatus according to the present invention and the relevant board-type device will be explained with reference to the drawings. However, the present invention is not limited to the following embodiment.

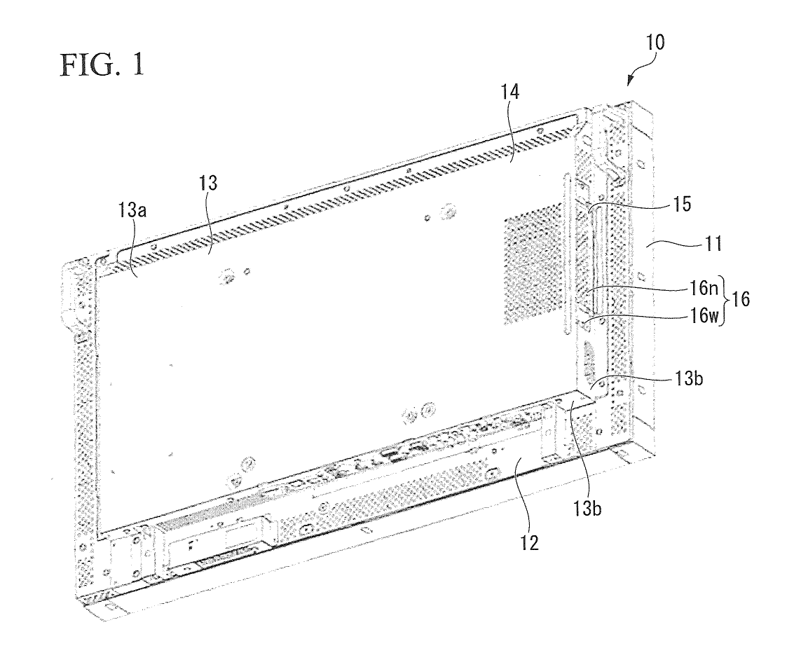

FIG. 1 is a perspective view that shows the back side of a display apparatus 10 according to an embodiment of the present invention.

As shown in FIG. 1, the display apparatus 10 of the present embodiment has an outer frame formed by a monitor 11 that displays information such as static images, video images, or the like, and a back chassis 12 (the chassis of the present invention) provided on the back side of the monitor 11.

The back chassis 12 contains a controller board that controls the operation of the monitor 11, a connection board utilized for connecting the apparatus to an external device, a speaker, and the like.

The back chassis 12 has a device container 13 that may be have a rectangular area which protrudes backward from the monitor 11.

The device container 13 is covered with a back cover 14 that covers a back surface 13a and four side surfaces 13b of the device container 13. The back cover 14 is detachably attached to the back chassis 12 by means of screws or the like. In the back cover 14, a slot opening 15 is formed in a surface that covers a side surface 13b of the device container 13.

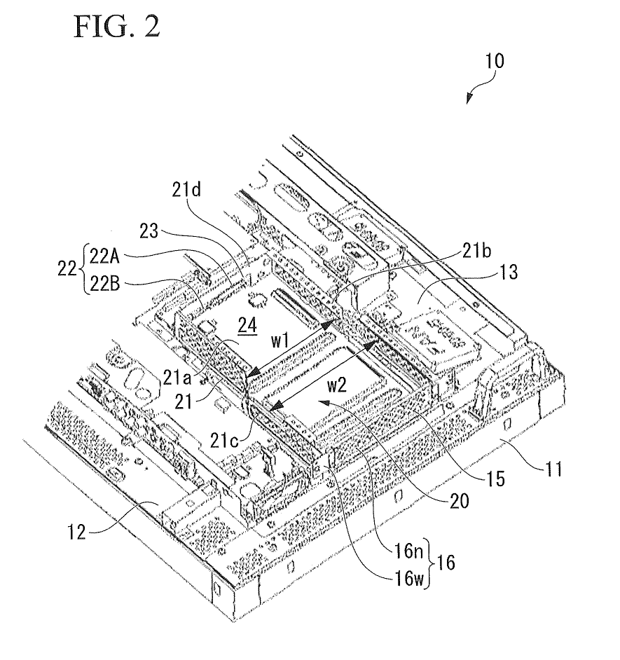

FIG. 2 shows a view observed when the back cover 14 (see FIG. 1) of the back chassis 12 is detached.

As shown in FIG. 2, in the device container 13 which is covered with the back cover 14, a device attachment slot 20 extends from the slot opening 15 towards the inside of the device container 13.

The device attachment slot 20 has a slot chassis 21 that contains a first board-type device 30 (i.e., the board-type device or option board in the present invention) explained later, and a connector 22 provided at the slot chassis 21.

The slot chassis 21 is made using a metal plate, and includes (i) a base plate 21a fastened to the device container 13 by means of screws or the like, (ii) side plates 21b and 21c which are vertically arranged on both sides of the base plate 21a so that the plates extend from the slot opening 15 to the back of the device container 13, and (iii) a back plate 21 provided at the innermost part of the device attachment slot 20.

The side plates 21b and 21c each have a cranked part in a middle part thereof, so that the back side of the device container 13 has a first width w1, and the side towards the slot opening 15 has a second width w2 that is greater than the first width w1.

The connector 22 is fastened to the base plate 21a in a manner such that the connector 22 faces a device housing space 24, that is surrounded by the side plates 21b and 21c and the back plate 21d, from an opening 23 formed in the back plate 21d.

In the present embodiment, the connector 22 includes two types that are a first male connector 22A (i.e., the (first) apparatus-side connector of the present invention) and a second female connector 22B (i.e., the (second) apparatus-side connector of the present invention). The first male connector 22A that may have 60 pins is larger than the second female connector 22B that may have 30 pins. The first male connector 22A and the second female connector 22B are arranged side by side along the surface of the base plate 21a.

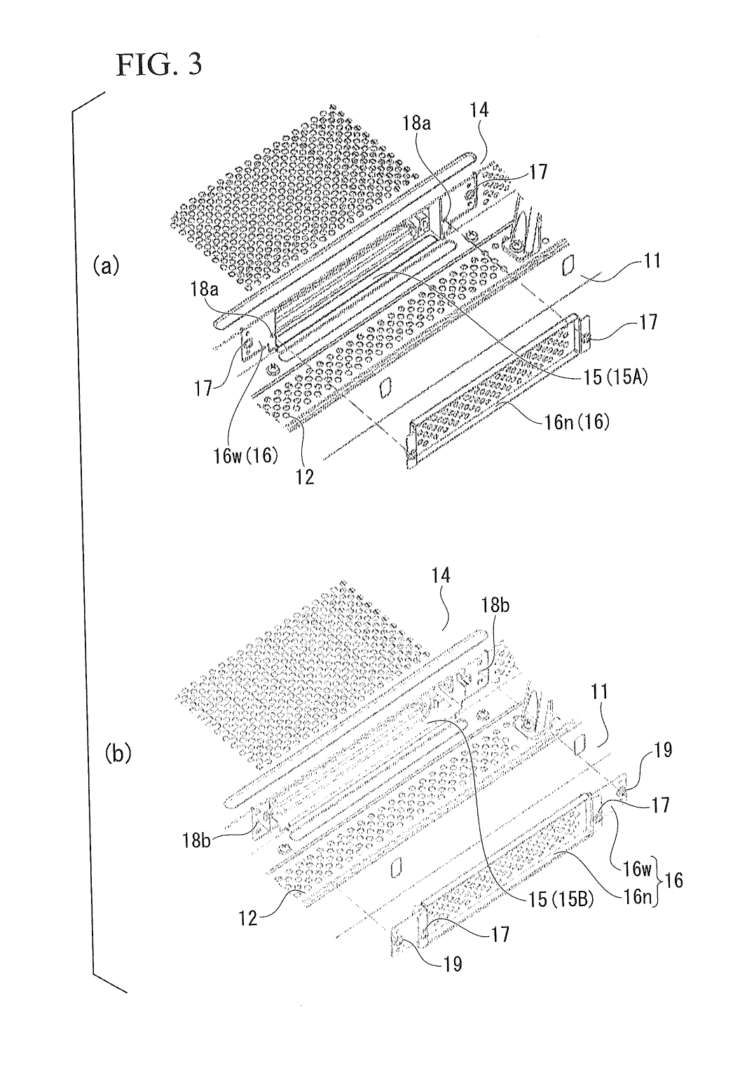

As shown in FIG. 3, the slot opening 15 joined to the above-described device attachment slot 20 can be closed using a cover 16. The cover 16 consists of a first cover body 16n having a plate shape and a second cover body 16w provided at the outer periphery of the first cover body 16n.

As shown in part (a) of FIG. 3, the second cover body 16w is detachably attached by means of screws 17 to the side surface 13b at which the slot opening 15 of the back cover 14 is provided, so that the second cover body 16w is attached on the outer periphery of the first cover body 16n. The second cover body 16w may be U-shaped with all corners in straight angles, so that when it is attached to the outer periphery of the first cover body 16n, it can close an opening that has a width greater than that of the first cover body 16n. Therefore, the second cover body 16w has screw holes 18a formed at inside ends thereof. The first cover body 16n can be joined to the inner side of the second cover body 16w by engaging the screws 17 with the screw holes 18a. The slot opening 15 has a size corresponding to the outer size of the combination of the first cover body 16n and the second cover body 16w.

As shown in part (b) of FIG. 3, the back cover 14 has screw holes 18b formed in an outer peripheral area of the slot opening 15. The second cover body 16w can be fastened to the side surface 13b, at which the slot opening 15 of the back cover 14 is provided, by engaging screws 19 with the screw holes 18b.

In the above-described cover 16, as shown in part (a) of FIG. 3, only the second cover body 16w can be detached by disengaging the screws 17 while the second cover body 16w is fastened to the back cover 14. In addition, as shown in part (b) of FIG. 13, the first cover body 16n and the second cover body 16w can be integrally detached by disengaging the screws 19 while the first cover body 16n and the second cover body 16w are joined to each other.

Accordingly, the opening size of the slot opening 15 can be selected between two values: one that corresponds to the first cover body 16n (the relevant opening may be called an opening 15A) and the other that corresponds to the second cover body 16w (the relevant opening may be called an opening 15B).

To the above-described device container 13, one of board-type devices of different types can be attached. Below, such board-type devices attachable to the device container 13 will be explained.

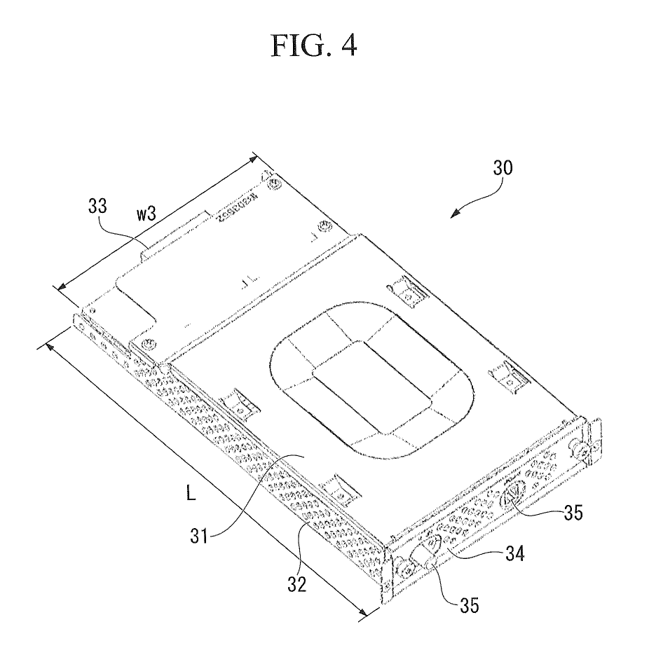

FIG. 4 shows an example of the board-type devices attachable to the device container 13.

In FIG. 4, a first board-type device 30 may have the largest size attachable to the device container 13 in the present embodiment, and has a device main body 31 (i.e., the first device main body of the present invention) and a chassis 32 (i.e., the first chassis of the present invention) that supports the device main body 31.

The device main body 31 may be an SBC (small board computer), a TV tuner board, a chain board, a media board, or the like. The device main body 31 has a first female connector 33 to be engaged with the above-described first male connector 22A.

The chassis 32 is made using a metal plate, and width w3 thereof corresponds to the narrower second width w1 for the back side of the side plates 21b and 21c in the slot chassis 21.

The chassis 32 has a connector plate 34 that closes the slot opening 15 when the chassis 32 is attached to the device attachment slot 20. The connector plate 34 is formed to satisfy standardized dimensions identical to those of the first cover body 16n. Therefore, in place of the first cover body 16n, the connector plate 34 can be attached to the inner side of the second cover body 16w by engaging the screws 17 with the screw holes 18a at the inside ends of the second cover body 16w. Additionally, a connector 35 (first device-side connector) utilized for connecting the device main body 31 to an external device can be provided at the connector plate 34.

The chassis 32 has a depth (dimension) L by which the connector plate 34 can be attached to the inner side of the second cover body 16w while the first male connector 22A is engaged with the first female connector 33.

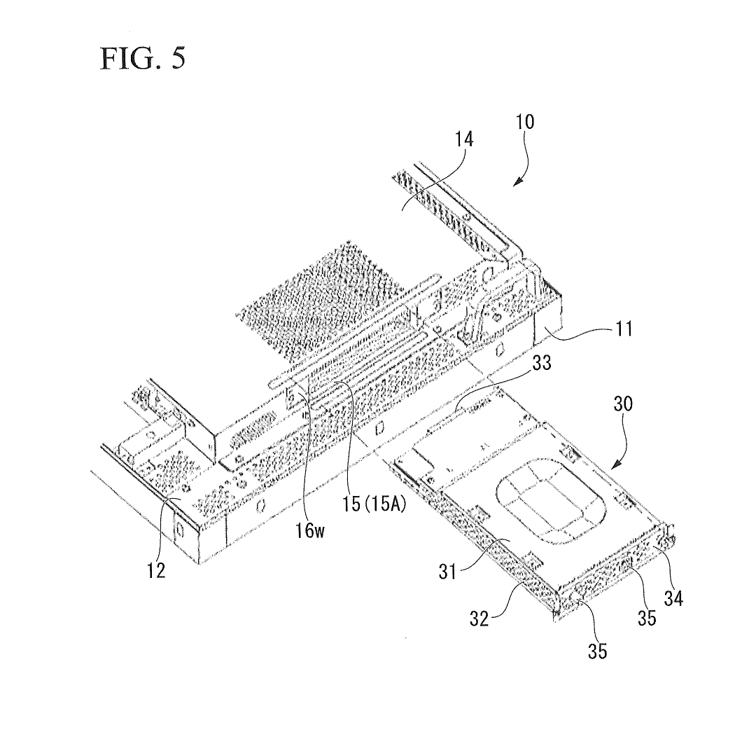

As shown in FIG. 5, the above-described first board-type device 30 is inserted into the device attachment slot 20 through the opening 15A of the slot opening 15 while the second cover body 16w is fastened to the relevant side surface 13b through the back cover 14, where the opening 15A is formed by detaching only the first cover body 16n by disengaging the screws 17.

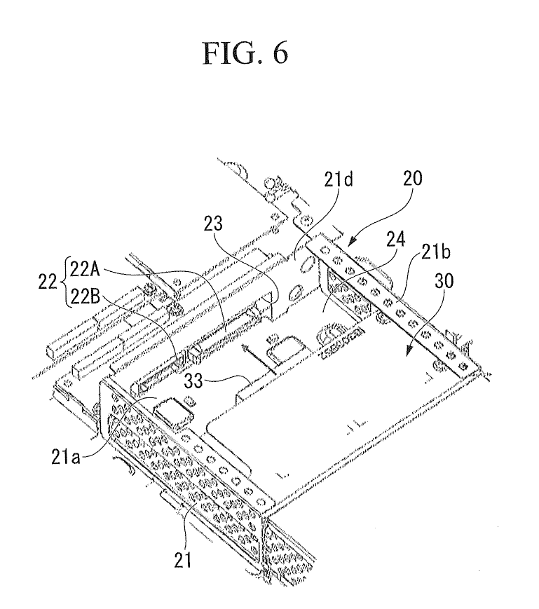

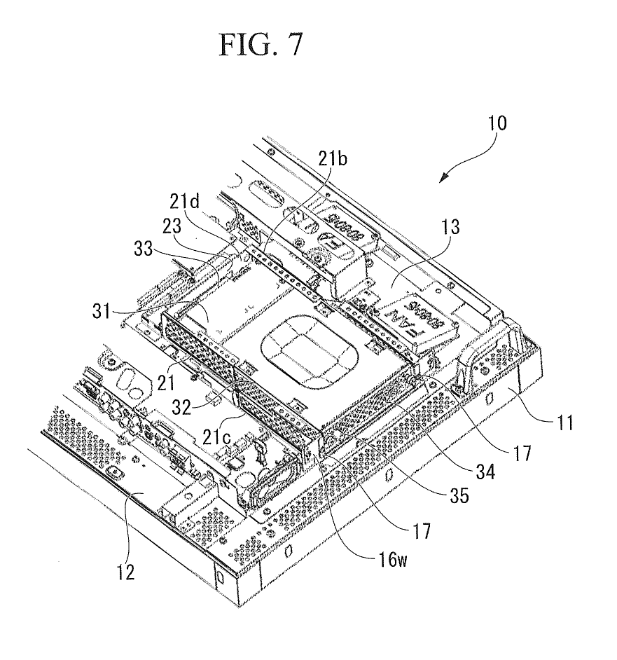

As shown in FIG. 6, the first board-type device 30 is inserted up to the innermost part of the device attachment slot 20, and the first female connector 33 is engaged with the first male connector 22A. Furthermore, as shown in FIG. 7, the connector plate 34 is fixed by engaging the screws 17 with the screw holes 18a formed at the inside ends of the second cover body 16w, so that the opening 15A is closed.

Here, as shown in FIG. 6, in the device attachment slot 20, the second female connector 22B is provided at a position adjacent to that of the first male connector 22A. When the first board-type device 30 is attached to the device attachment slot 20 and the female connector thereof is engaged with the first male connector 22A, the first male connector 22A is smaller than the second female connector 22B and generally the female connector less protrudes than the male connector engaged therewith. Therefore, it is possible to prevent the female connector from interfering with the second female connector 22B.

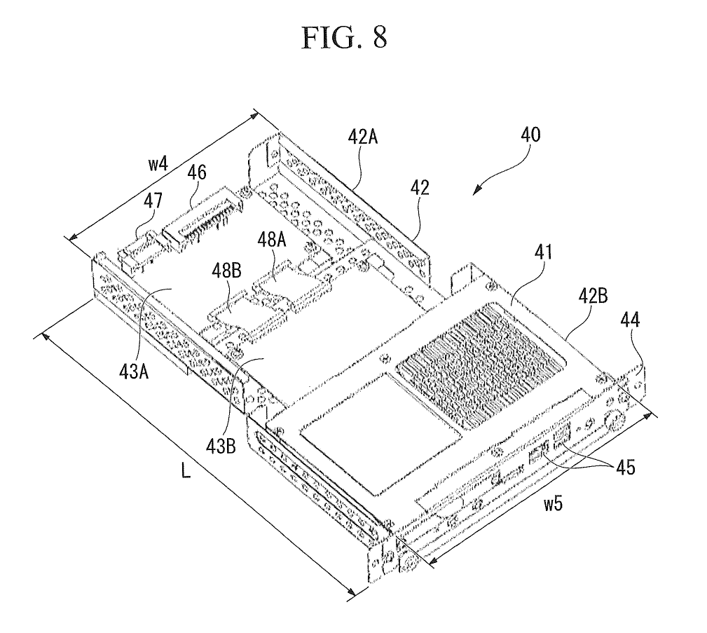

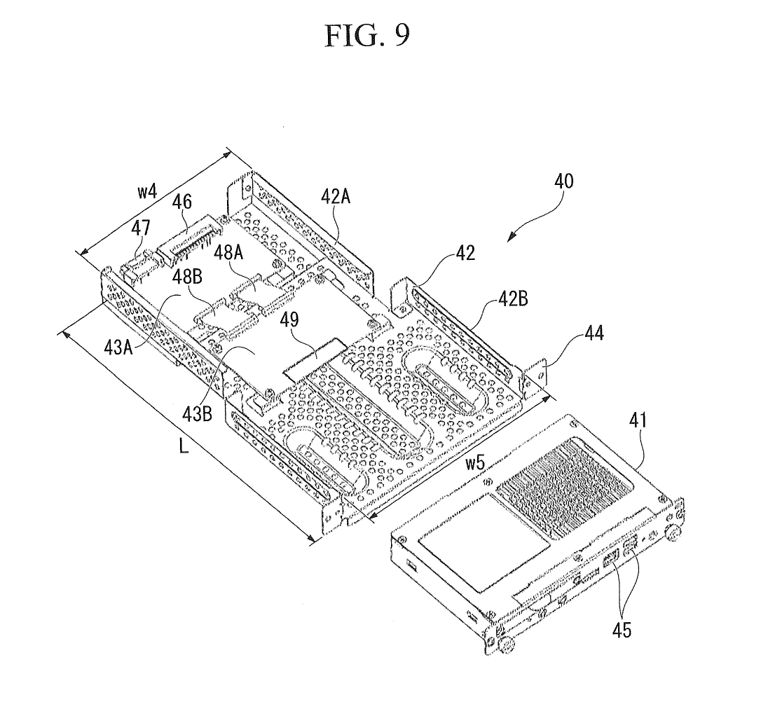

FIGS. 8 and 9 show another example of the board-type devices attachable to the device container 13.

In FIGS. 8 and 9, a second board-type device 40 (i.e., the board-type device or option board in the present invention) has a device main body 41 (i.e., the second device main body of the present invention), a chassis 42 (as the second chassis) that supports the device main body 41, a first adaptor board 43A (i.e., the connection wiring unit, the electric circuit board, or the first electric circuit board of the present invention), and a second adaptor board 43B (i.e., the connection wiring unit, the electric circuit board, or the second electric circuit board of the present invention).

The device main body 41 is smaller than the device main body 31 of the first board-type device 30 but has a greater width than that of the device main body 31. The device main body 41 may be an SBC.

The chassis 42 is made using a metal plate, and has the same depth L as that of the chassis 32 of the first board-type device 30. The chassis 42 includes (i) a part 42A having a width w4 that corresponds to the first width w1 for the back side of the side plates 21b and 21c, and (ii) a part 42B having a width w5 (>w4) that corresponds to the wider second width w2 (>w1) for the front side (towards the slot opening 15) of the side plates 21b and 21c.

In the chassis 42, the device main body 41 is contained in the part 42B having the width w5 that corresponds to the second width w2 for the front side (towards the slot opening 15) of the side plates 21b and 21c.

The first and second adaptor boards 43A and 43B are contained in the part 42A having the width w4 that corresponds to the narrower first width w1 for the back side of the side plates 21b and 21c. One end of the first adaptor board 43A has a first female connector 46 and a second male connector 47 which are respectively engaged with the above-described first male connector 22A and the second female connector 22B. The first and second adaptor boards 43A and 43B have a wiring pattern for electrically connecting the first female connector 46 and the second male connector 47 to the device main body 41. Specifically, the first and second adaptor boards 43A and 43B function as wiring (or harness) for electrically connecting the first female connector 46 and the second male connector 47 to the device main body 41.

In addition, the first and second adaptor boards 43A and 43B are connected to each other via connection harnesses 48A and 48B. The first adaptor board 43A is arranged such that the level thereof conforms to the first female connector 46 and the second male connector 47. The second adaptor board 43B is arranged such that the level thereof conforms to the device main body 41. Accordingly, there is a step between the first and second adaptor boards 43A and 43B. The connection harnesses 48A and 48B are flexible so as to absorb the step between the first and second adaptor boards 43A and 43B.

As shown in FIG. 9, the device main body 41 is electrically connected to the second adaptor board 43B via an electrode pad 49 formed on a surface of the second adaptor board 43B.

The chassis 42 has a connector plate 44 which closes the slot opening 15 when the chassis 42 is attached to the device attachment slot 20. The connector plate 44 is formed to satisfy standardized dimensions identical to those of the second cover body 16w. Therefore, in place of the first cover body 16n and the second cover body 16w, the connector plate 44 can be attached to the back cover 14 by engaging the screws 19 with the screw holes 18b.

In addition, the device main body 41 is fastened to the connector plate 44, and connector(s) 45 (second device-side connector) for connecting with external device(s) may be provided in the connector plate 44.

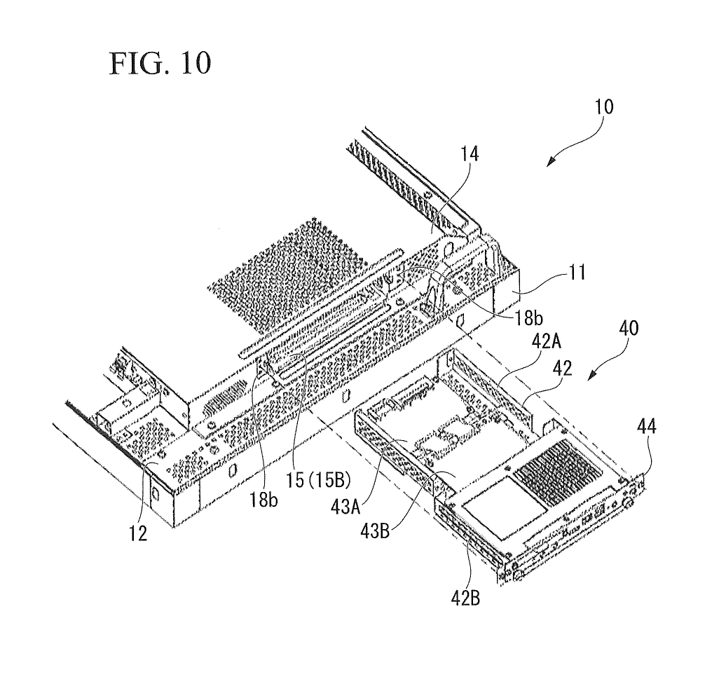

As shown in FIG. 10, the above-described second board-type device 40 is inserted into the device attachment slot 20 through the opening 15B of the slot opening 15, where the opening 15B is formed by detaching the first cover body 16n and the second cover body 16w by disengaging the screws 19.

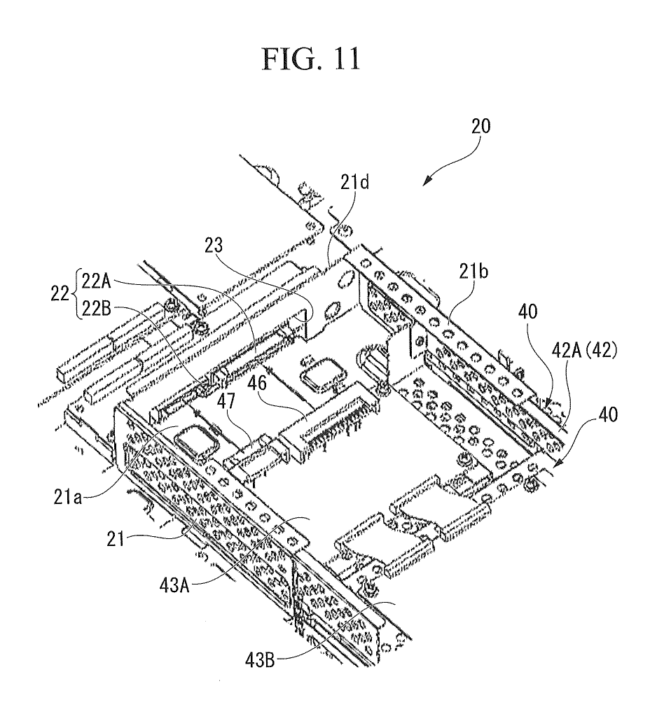

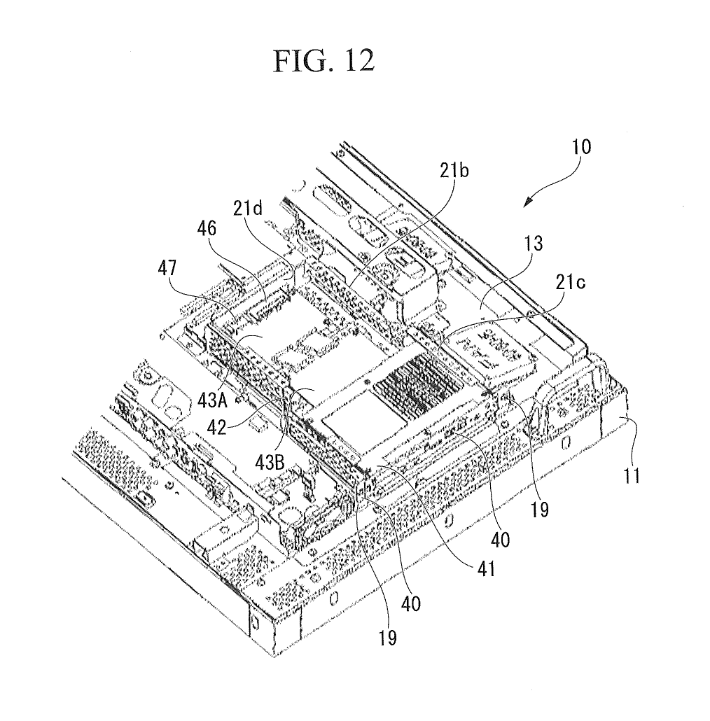

As shown in FIG. 11, the second board-type device 40 is inserted up to the innermost part of the device attachment slot 20, the first female connector 46 is engaged with the first male connector 22A, and the second male connector 47 is engaged with the second female connector 22B. Furthermore, as shown in FIG. 12, the connector plate 44 is fixed by engaging the screws 19 so that the opening 15B is closed.

According to the display apparatus 10 of the present embodiment having the above-described structure, in the second board-type device 40, the device main body 41 is connected to the apparatus-side connector 22 via the first and second adaptor boards 43A and 43B. Therefore, even the device main body 41, that has a smaller depth than that of the chassis 42 whose depth coincides with the depth L of the first board-type device 30, can be attached to the device attachment slot 20.

Additionally, the side plates 21b and 21c in the display apparatus 10 produce the first width w1 and the second width w2. Therefore, at least the first board-type device 30 and the second board-type device 40 having different widths can each be attached to the device attachment slot 20.

Since such different types (the first board-type device 30 and the second board-type device 40) can each be attached to the device attachment slot 20, multi-functional characteristics of the display apparatus 10 can be improved without increasing the device attachment slot 20 and also increasing the size of the display apparatus 10

Additionally, since the second board-type device 40 has a two-board formation consisting of the first and second adaptor boards 43A and 43B, even a step can be handled.

In the first board-type device 30, electric connection is established only utilizing the first male connector 22A and the first female connector 33. By contrast, electric connection of the second board-type device 40 is established utilizing two engagements of one pair of the first male connector 22A and the first female connector 46 and the other pair of the second female connector 22B and the second male connector 47. Therefore, connection can be established even using different types of connectors.

In addition, the slot opening 15 of the device attachment slot 20 can be closed utilizing the first cover body 16n and the second cover body 16w that covers the outer periphery of the first cover body 16n. Therefore, the slot opening 15 can be closed in the case of either inserting the first board-type device 30 or the second board-type device 40, in a manner that conforms to the size of the relevant board-type device.

The present invention is not limited to the above-described embodiment that has been explained with reference to the drawings, and various modifications are possible in the technical range of the present invention.

For example, the respective device main bodies 31 and 41 of the first board-type device 30 and the second board-type device 40 may each be applied to any purpose. In addition, the device main bodies 31 and 41 each have any size if they can be respectively contained in the chassis 32 and 42.

In addition, although two types of board-type devices such as the first board-type device 30 and the second board-type device 40 can be exchangeably attached to the device attachment slot 20 in the present embodiment, a structure for detachably attaching three or more types of board-type devices is, of course, possible.

Other than the above-described examples, the structural elements shown in the above embodiment can be appropriately chosen or modified without departing from the scope of the present invention.

### INDUSTRIAL APPLICABILITY

According to the option board exchange mechanism in a display apparatus, and the display apparatus of the present invention, board-type devices based on different standards can be exchangeably attached to a device attachment slot of a display apparatus such as a monitor. Therefore, multi-functional characteristics of the display apparatus can be improved without increasing the size of the display apparatus.

### REFERENCE SYMBOLS

10 display apparatus
12 back chassis (chassis)
13 device container
14 back cover
15 slot opening
15A opening
15B opening
16 cover
16n first cover body
16w second cover body
20 device attachment slot
21 slot chassis
22 connector
22A first male connector (apparatus-side connector, first apparatus-side connector)
22B second female connector (apparatus-side connector, second apparatus-side connector)
23 opening
24 device housing space
30 first board-type device (board-type device, option board)
31 device main body (first device main body)
33 first female connector
34 connector plate
35 connector (first device-side connector)
40 second board-type device (board-type device, option board)
41 device main body (second device main body)
42 chassis (second chassis)
43A first adaptor board (connection wiring unit, electric circuit board, first electric circuit board)
43B second adaptor board (connection wiring unit, electric circuit board, second electric circuit board)
44 connector plate
45 connector (second device-side connector)
46 first female connector
47 second male connector
48A, 48B connection harness

1. An option board exchange mechanism in a display apparatus to which board-type devices of different types can be selectably attached, wherein:
the display apparatus comprises:
a device housing slot that extends from a slot opening formed in a chassis of the apparatus towards the inside of the chassis and can selectably contain at least a first board-type device and a second board-type device which have different forms; and
an apparatus-side connector provided at an innermost part of the device housing slot;
the first board-type device comprises a first device main body, a first chassis that supports the first device main body, and a first connector that is connected to the apparatus-side connector; and
the second board-type device comprises:
a second device main body that has a smaller depth dimension than that of the first device main body with respect to an insertion direction for the device housing slot;
a second chassis that supports the first device main body and has the same depth dimension as that of the first chassis,;
a second connector that is connected to the apparatus-side connector; and
a connection wiring unit fastened to the second chassis, where the connection wiring unit electrically connects the second device main body to the second connector.

2. The option board exchange mechanism in accordance with claim 1, wherein:
in the second chassis, a back side in the insertion direction for the device housing slot has a first width that is the same as a width of the first chassis, and a front side in said insertion direction has a second width that is greater than the width of the first chassis; and
in the device housing slot, a back side in said insertion direction has a width that corresponds to the first width, and a front side in said insertion direction has a width that corresponds to the second width.

3. The option board exchange mechanism in accordance with claim 2, wherein:
a cover for closing the slot opening is provided; and
the cover has a first cover body whose width corresponds to the first width, and a second cover body whose width corresponds to the second width, where the second cover body has an opening to which the first cover body can be attached.

4. The option board exchange mechanism in accordance with claim 1, wherein:
the apparatus-side connector has at least a first apparatus-side connector and a second apparatus-side connector;
the first connector is connected to at least the first apparatus-side connector; and
the second connector is connected to at least the second apparatus-side connector.

5. The option board exchange mechanism in accordance with claim 4, wherein:
the first apparatus-side connector is a male connector;
the second apparatus-side connector is a female connector; and
the second connector has a first female connector that is connected to the first apparatus-side connector, and a second male connector that is connected to the second apparatus-side connector.

6. The option board exchange mechanism in accordance with claim 1, wherein the connection wiring unit is an electric circuit board.

7. The option board exchange mechanism in accordance with claim 6, wherein:
the electric circuit board includes a first electric circuit board and a second electric circuit board;
the first electric circuit board is connected to the second connector;
the second electric circuit board is connected to the second device main body; and
the first electric circuit board and the second electric circuit board are arranged to have a step therebetween.

8. A display apparatus to which board-type devices of different types can be selectably attached, the display apparatus comprising:
a device housing slot that extends from a slot opening formed in a surface of a chassis of the apparatus towards the inside of the chassis and can selectably contain at least a first board-type device and a second board-type device; and
an apparatus-side connector provided at an innermost part of the device housing slot,
wherein in the device housing slot, a back side has a first width and a front side towards the slot opening has a second width that is greater than the first width.
